(19) United States
(12) Patent Application Publication
(10) Pub. No.: US 2009/0163016 A1
(43) Pub. Date: Jun. 25, 2009

(54) METHOD OF FABRICATING A SEMICONDUCTOR DEVICE INCLUDING METAL GATE ELECTRODE AND ELECTRONIC FUSE

(75) Inventors: Min-Chul SUN, Gyeonggi-do (KR); Jin-Woo KIM, Gyeonggi-do (KR); Hyung-Suk JUNG, Gyeonggi-do (KR)

Correspondence Address: MARGER JOHNSON & MCCOLLOM, P.C., 210 SW MORRISON STREET, SUITE 400, PORTLAND, OR, 97204, US

(73) Assignee: SAMSUNG ELECTRONICS CO., LTD., Gyeonggi-do (KR)

(21) Appl. No.: 12/336,305

(22) Filed: Dec. 16, 2008

(30) Foreign Application Priority Data
Dec. 21, 2007 (KR) 2007-0135234

(51) Int. Cl. H01L 21/28

(52) U.S. Cl. 438/592; 257/E21.19

(57) ABSTRACT

A method of fabricating a semiconductor device including a metal gate electrode and an electronic fuse. The method may include forming a gate dielectric layer on a semiconductor substrate, forming a first metal layer on the gate dielectric layer, forming a portion of the first metal layer in a first device region, forming a second metal layer on the semiconductor substrate comprising the portion of the first metal layer, forming a portion of the second metal layer in a second device region, forming a low-resistance layer on the semiconductor substrate comprising the portion of the first metal layer and the portion of the second metal layer, and patterning the low-resistance layer to form gate electrodes, and a fuse pattern of the low-resistance layer in a fuse region.

### CROSS-REFERENCE TO RELATED PATENT APPLICATION

This application claims the benefit of Korean Patent Application No. 10-2007-0135234, filed on Dec. 21, 2007, in the Korean Intellectual Property Office, the disclosure of which is incorporated herein in its entirety by reference.

### BACKGROUND

1. Field of the Invention

Embodiments of the present invention relate to a semiconductor device and a method of fabricating the same, and particularly to a method of fabricating a semiconductor device including a metal gate electrode and an electronic fuse.

2. Description of the Related Art

As a metal-oxide-semiconductor field-effect transistor (MOSFET) is scaled down, a gate dielectric layer becomes thinner. However, direct tunneling exponentially increases if a thickness of SiO₂ (which may be used for the gate dielectric layer) becomes smaller than a predetermined gate oxide equivalent thickness (tox_{eq}<1.5 nm). Therefore, research has been conducted to replace SiO₂ with a material having a high dielectric constant (i.e., a high-k dielectric material) that can maintain the same MOSFET driving current capacity while allowing the use of a gate dielectric layer with a sufficient thickness.

If polycrystalline silicon is used for a gate electrode and a material having a high dielectric constant (i.e., a high-k dielectric material) is used for a gate dielectric layer, then degradation of device characteristics occurs because of an intermediate material generated at an interface between the polycrystalline silicon and the high-k dielectric material. To prevent the generation of the intermediate material, a metal material is used for the gate electrode, together with the high-k dielectric layer, and the device characteristics can be improved by increasing an on-current and decreasing an off-current.

FIG. 1 illustrates a gate electrode structure employing a high-k dielectric gate dielectric layer and a metal gate. The gate electrode 20 of FIG. 1 includes a high-k gate dielectric layer 22 on a semiconductor substrate 10, a gate electrode layer 24 and a low-resistance gate electrode layer 26. Source/drain regions 12 are formed in the semiconductor substrate 10 at both sides of the gate electrode 20. If a metal gate electrode is employed, an electrically programmable fuse being formed simultaneously with the metal gate electrode also includes a metal layer. In this case, defective fuse operation may occur because resistance of the electrically programmable fuse cannot be increased.

A general operational principle of the electrically programmable fuse will now be described with reference to FIGS. 2 through 4. FIG. 2 is a circuit diagram of an electrically programmable fuse block. FIG. 3 is a cross-sectional view of a conventional fuse. And FIG. 4 is a top view of the conventional fuse. Referring to FIG. 2, the electrically programmable fuse block includes a transistor 1 and a fuse 3 that are connected in series. Referring to FIG. 3, the fuse 3 has a stack structure of a doped polycrystalline silicon layer 34 and a silicide layer 36 on the polycrystalline silicon layer 34. Referring to FIG. 4, the fuse 3 includes a cathode 4, a fuse link 5 and an anode 6. The cathode 4 is connected to a drain of the transistor 1. When the transistor 1 is turned on, overcurrent occurs at the fuse 3, causing electromigration in the silicide layer 36. Because of the electromigration, silicide is removed in a portion of the fuse link 5 and only the polycrystalline silicon layer 36 remains. Thus, the fuse 3 is substantially opened and the resistance is significantly increased. However, if the gate electrode structure as illustrated in FIG. 1 is employed, a fuse is not opened because an increase in resistance of the fuse is prevented by the metal layer of a lower portion of the fuse remaining even after a silicide layer at an upper portion of the fuse is blown away by the overcurrent.

### SUMMARY

Embodiments of the present invention provide a semiconductor device including a metal gate electrode and an electronic fuse.

Embodiments of the present invention also provides a method of fabricating a semiconductor device including a metal gate electrode and an electronic fuse.

According to embodiments of the present invention, a fuse formed simultaneously with a metal gate electrode does not include a metal layer.

According to an embodiment of the present invention, there is provided a semiconductor device including: a semiconductor substrate; a gate dielectric layer on the semiconductor substrate; a first device region comprising a first metal gate electrode on the gate dielectric layer; a second device region comprising a second metal gate electrode on the gate dielectric layer; and a fuse region comprising a low-resistance layer on the gate dielectric layer.

The first metal gate electrode may include: a portion of a first metal layer; a first portion of a second metal layer on the portion of the first metal layer; and a first low-resistance pattern on the first portion of the second metal layer.

Alternatively, the first metal gate electrode may include: an alloy metal pattern; a first portion of a second metal layer on the alloy metal pattern; and a first low-resistance pattern on the first portion of the second metal layer.

According to another aspect of the present invention, there is provided a method of fabricating a semiconductor device comprising a first device region, a second device region and a fuse region, including: forming a gate dielectric layer on the semiconductor substrate; forming a first metal layer on the gate dielectric layer; forming a portion of the first metal layer in the first device region; forming a second metal layer on the semiconductor substrate comprising the portion of the first metal layer; forming a portion of the second metal layer in the second device region; forming a low-resistance layer on the semiconductor substrate comprising the portion of the first metal layer and the portion of the second metal layer; and patterning the low-resistance layer to form a first gate electrode comprising the portion of the first metal layer and a first low-resistance pattern in the first device region, a second gate electrode comprising the portion of the second metal layer and a second low-resistance pattern in the second device region, and a fuse pattern of the low-resistance layer in the fuse region.

According to another aspect of the present invention, there is provided a method of fabricating a semiconductor device comprising a first device region, a second device region and a fuse region, including: forming a gate dielectric layer on a semiconductor substrate; sequentially forming a first metal layer and an intermediate metal layer on the gate dielectric layer; forming an intermediate metal pattern from the intermediate metal layer in the first device region; forming a second metal layer on the semiconductor substrate comprising the intermediate metal pattern; forming a stack pattern comprising a first portion of the first metal layer, the intermediate metal pattern and a first portion of the second metal layer in the first device region, and a stack pattern comprising a second portion of the first metal layer and a second portion of the second metal layer in the second device region; forming a low-resistance layer on the semiconductor substrate comprising the stack patterns; and patterning the low-resistance layer to form a first gate electrode in the first device region, a second gate electrode in the second device region and a fuse pattern of the low-resistance layer in the fuse region.

### BRIEF DESCRIPTION OF THE DRAWINGS

The above and other features and advantages of the present invention will become more apparent by describing in detail exemplary embodiments thereof with reference to the attached drawings in which:

FIG. 1 is a cross-sectional view illustrating a gate electrode including a high-k gate dielectric layer and a metal gate;

FIG. 2 is a circuit diagram of an electrically programmable fuse block;

FIG. 3 is a cross-sectional view illustrating a conventional electrically programmable fuse;

FIG. 4 is a top view of the conventional electrically programmable fuse;

FIGS. 5A through 5E are cross-sectional views for describing a method of fabricating a semiconductor device including a metal gate electrode and an electronic fuse, according to some embodiments of the present invention;

FIGS. 6A through 6E are cross-sectional views for describing a method of fabricating a semiconductor device including a metal gate electrode and an electronic fuse, according to some embodiments of the present invention; and

FIGS. 7A through 7F are cross-sectional views for describing a method of fabricating a semiconductor device including a metal gate electrode and an electronic fuse, according to some embodiments of the present invention.

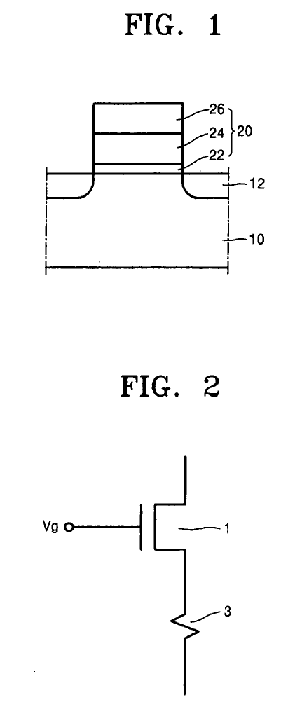

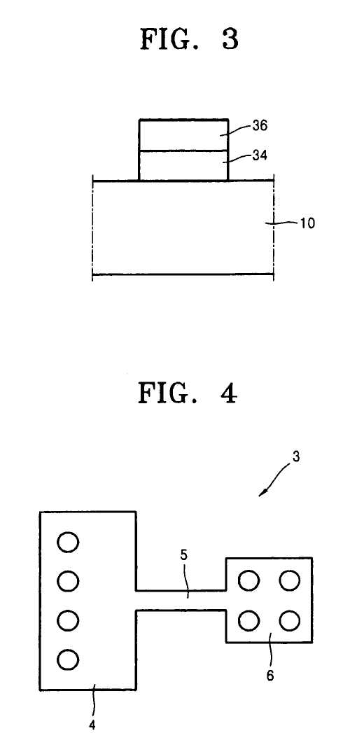

### DETAILED DESCRIPTION

The present invention will now be described more fully with reference to the accompanying drawings, in which exemplary embodiments of the invention are shown. The invention may, however, be embodied in many different forms and should not be construed as being limited to the embodiments set forth herein; rather, these embodiments are provided so that this disclosure will be thorough and complete, and will fully convey the concept of the invention to those skilled in the art. In the drawings, the thicknesses of layers and regions are exaggerated for clarity. Like reference numerals in the drawings denote like elements, and thus their description will be omitted.

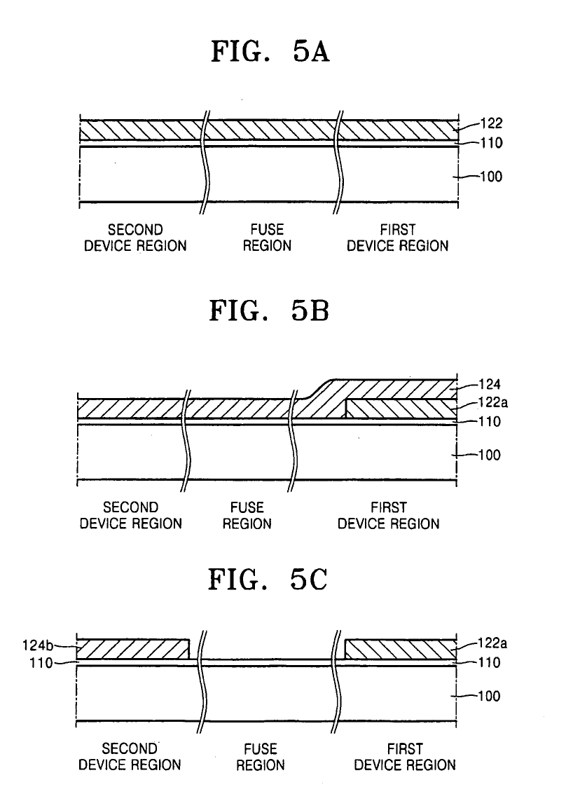

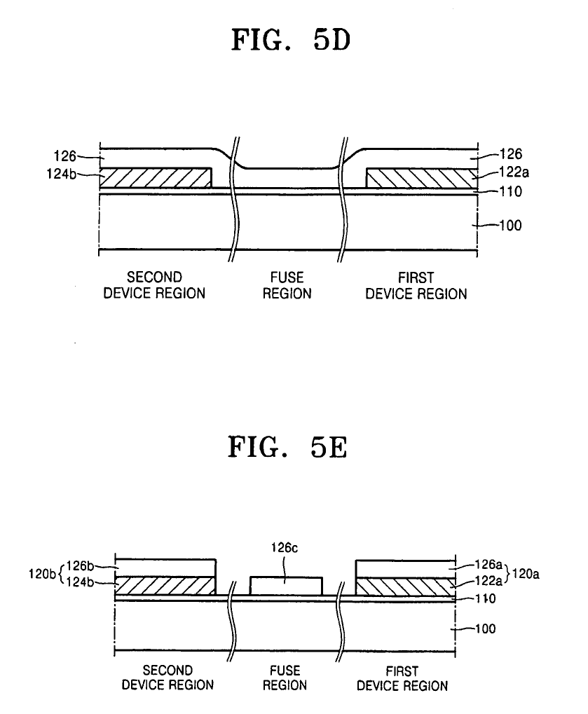

FIGS. 5A through 5E, FIGS. 6A through 6E and FIGS. 7A through 7F are cross-sectional views for describing a method of fabricating a semiconductor device including a metal gate electrode and an electronic fuse, according to some embodiments of the present invention.

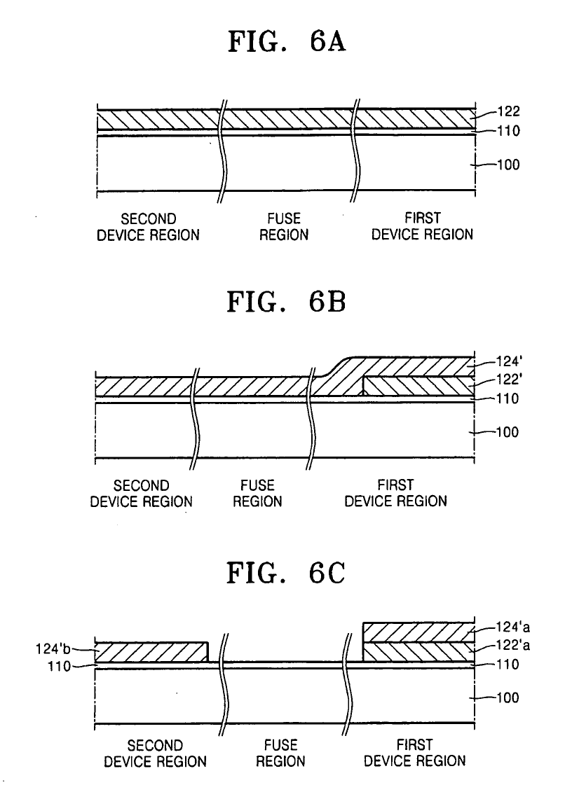

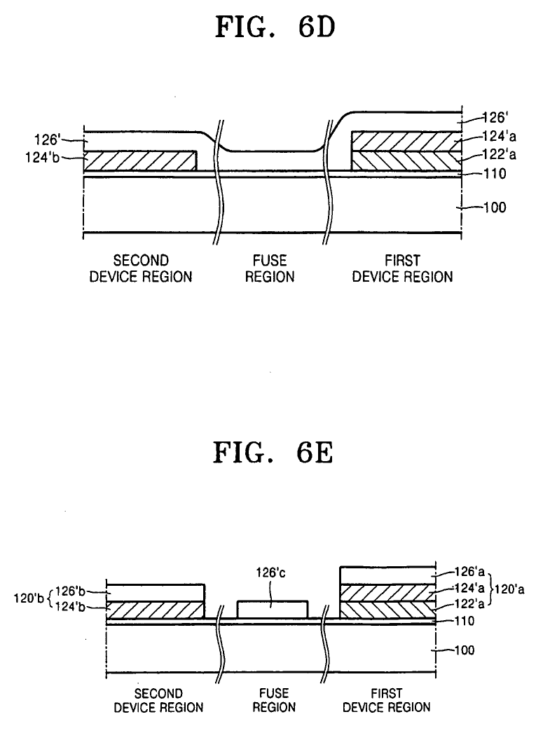

A gate electrode and an electronic fuse of a semiconductor device will now be described with reference to FIGS. 5E and 6E. The semiconductor device of FIG. 5E includes a first device region, a second device region and a fuse region. The first device region may be an n-type metal-oxide-semiconductor (NMOS) device region and the second device region may be a p-type metal-oxide-semiconductor (PMOS) device region. Conversely, the first device region may be a PMOS device region and the second device region may be an NMOS device region. In the first device region and the second device region, first and second gate electrodes 120a and 120b comprise metal materials having different work functions. The first gate electrode 120a is formed in the first device region, and the second gate electrode 120b is formed in the second device region. The first gate electrode 120a may have a stack structure of a first metal layer 122a and a silicide layer 126a. The second gate electrode 120b may have a stack structure of a second metal layer 124b and a silicide layer 126b. The second metal layer 124b may be formed of a material different from that of the first metal layer 122a.

A fuse pattern 126c may be formed in the fuse region. The fuse pattern 126c may be formed on the same plane as the first and second gate electrodes 120a and 120b. The fuse pattern 126c does not include a metal layer, and includes only a silicide layer. Thus, if overcurrent flows to the fuse pattern 126c by fuse program, transfer of atoms occurs at the silicide layer, so that the fuse is cut.

Like the semiconductor device of FIG. 5E, the semiconductor device of FIG. 6E includes first and second gate electrodes 120′a and 120′b, which may be formed of different metal materials in a first device region and a second device region, respectively. The gate electrodes 120′a and 120′b of FIG. 6E are different from the gate electrodes 120a and 120b of FIG. 5E in that the first gate electrode 120′a has a stack structure of a portion 122′a of a first metal layer, a first portion of a second metal layer 124′a and a first portion of a silicide layer 126′a, and a second gate electrode 120′b has a stack structure of a second portion of the second metal layer 124′b and a second portion of the silicide layer 126′b. In a fuse region of the semiconductor device of FIG. 6E, a fuse pattern 126′c having the same structure as the fuse pattern 126c of FIG. 5E may be formed. The fuse pattern 126′c may be formed on the same plane as the first and second gate electrodes 120′a and 120′b, but includes only a silicide layer and does not include a metal layer. Thus, when overcurrent flows to the fuse pattern 126c′ by the fuse program, electrical transfer of atoms forming the silicide layer occurs at the silicide layer included in the fuse region, so that the fuse is cut.

The semiconductor device according to the embodiments of the present invention can achieve high integration by employing the metal gate electrode structure, which can ensure low-resistance while accommodating the high-k gate dielectric layer. The gate dielectric layer may comprise a dielectric material having a high dielectric constant, such as 7 or higher. Since the fuse pattern formed simultaneously with the gate electrode structure includes only the silicide layer, and does not include a metal layer, electrical fusing may occur.

A method of forming a gate electrode and an electronic fuse of a semiconductor device according to an embodiment of the present invention will now be described with reference to FIGS. 5A through 5E.

Referring to FIG. 5A, a gate dielectric layer 110 may be formed on a semiconductor substrate 100. The substrate 100 may have a lower structure of bulk silicon or silicon-on-insulator (SOI). The gate dielectric layer 110 may be formed of a material having a high dielectric constant, i.e., a high-k dielectric material. For example, examples of the material of the gate dielectric layer 110 may include hafnium oxide, hafnium silicon oxide, lanthanum oxide, zirconium oxide, zirconium silicon oxide, tantalum oxide, barium strontium titanium oxide, barium titanium oxide, strontium titanium oxide, yttrium oxide, and aluminum oxide. A first metal layer 122 is formed on the gate dielectric layer 110.

Referring to FIG. 5B, the first metal layer 122 is removed in a second device region and a fuse region, and a portion 122a of the first metal layer 122 for a gate electrode is formed only in the first device region. Thereafter, a second metal layer 124 is formed on the semiconductor substrate 100 including the portion 122a of the first metal layer 122.

Referring to FIG. 5C, the second metal layer 124 is removed in the first device region and the fuse region, and a portion 124b of the second metal layer 124 for a gate electrode is formed only in the second device region.

The second metal layer 124 is formed of metal having different work function from the first metal layer 122. If the first device region is an NMOS region, the first metal layer 122 may be formed of, e.g., hafnium zirconium, titanium, tantalum, aluminum or an alloy thereof. If the second device region is a PMOS region, the second metal layer 124 may be formed of, e.g., ruthenium, palladium, platinum, titanium nitride, tungsten nitride, tantalum nitride, ruthenium nitride or titanium aluminum nitride.

Referring to FIG. 5D, the portion 122a of the first metal layer 122 and the portion 124b of the second metal layer 124 are formed in the first device region and the second device region, respectively. A low-resistance layer 126 is formed on the semiconductor substrate 100 including the entire fuse region in which the gate dielectric layer 110 is exposed. The low-resistance layer 126 may be formed of, e.g., silicide.

Referring to FIG. 5E, the low-resistance layer 126 is patterned to form a first low-resistance pattern 126a, a second low-resistance pattern 126b, and a fuse pattern 126c. The first and second gate electrode structures 120a and 120b, and the fuse pattern 126c, are thereby formed. That is, the first gate electrode 120a including the portion 122a of the first metal layer 122 and the first low-resistance pattern 126a is formed in the first device region, and the second gate electrode 120b including the portion 124b of the second metal layer 124 and the second low-resistance pattern 126b is formed in the second device region. In the fuse region, the fuse pattern 126c is formed, which includes only a portion of the low-resistance layer and does not include the metal layer. Thus, a semiconductor device including the gate electrode that includes the metal layer and the fuse that does not include the metal layer can be formed.

A method of forming a gate electrode and an electronic fuse of a semiconductor device according to another embodiment of the present invention will now be described with reference to FIGS. 6A through 6E.

As in FIGS. 5A and 5B, referring to FIGS. 6A and 6B, the gate dielectric layer 110 is formed on the semiconductor substrate 100, and a portion 122′a of the first metal layer 122, and a second metal layer 124′, are formed. Referring to FIG. 6C, the second metal layer 124′ is removed in a fuse region, and a first portion 124′a of the second metal layer 124′ is formed on the portion 122′a of the first metal layer of a first device region, and a second portion 124′b of the second metal layer 124′ is formed on the gate dielectric layer 110 of a second device region. In other words, the first portion 124′a of the second metal layer and the second portion 124′b of the second metal layer may be formed from the second metal layer 124′.

Referring to FIG. 6D, a low-resistance layer 126′ is formed on the semiconductor substrate 100 including the portion 122′a of the first metal layer and the first and second portions 124′a and 124′b of the second metal layer 124′. The low-resistance layer 126′ may be formed of, e.g., silicide.

Referring to FIG. 6E, the low-resistance layer 126′ is patterned to form a first low-resistance pattern 126′a, a second low-resistance pattern 126′b, and a fuse pattern 126′c. The first low-resistance pattern 126′a, the second low-resistance pattern 126′b, and the fuse pattern 126′c are each portions of the low-resistance layer 126′. The first and second gate electrodes 120′a and 120′b, and the fuse pattern 126′c, may thereby be formed. That is, the first gate electrode 120′a including the portion 122′a of the first metal layer, the first portion 124′a of the second metal layer, and the first low-resistance pattern 126′a is formed in the first device region. And the second gate electrode 120′b including the second portion 124′b of the second metal layer and the second low-resistance pattern 126′b is formed in the second device region. In the fuse region, the fuse pattern 126′c is formed, which includes only a portion of the low-resistance layer and does not include the metal layer. As shown in FIG. 6E, the first gate electrode 120′a of the first device region includes two layers of metal.

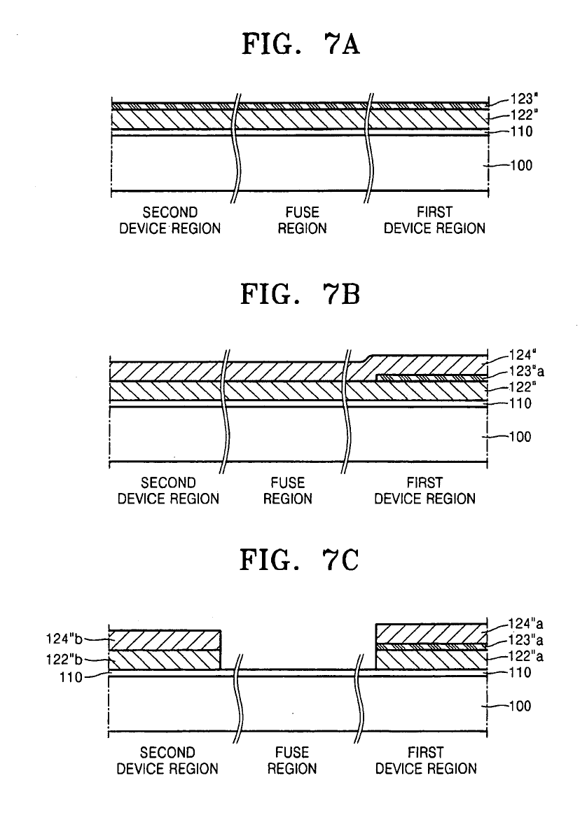

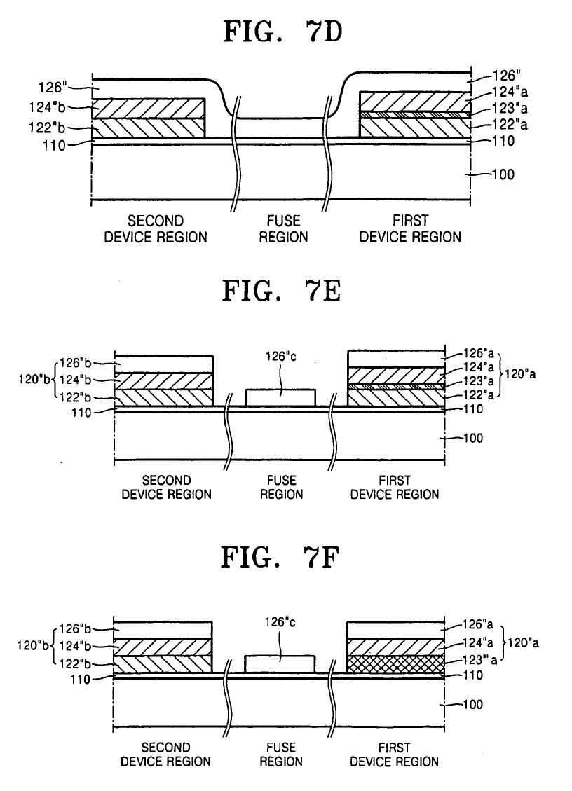

A method of forming a gate electrode and an electronic fuse of a semiconductor device according to another embodiment of the present invention will now be described with reference to FIGS. 7A through 7F. Referring to FIG. 7A, the gate dielectric layer 110, a first metal layer 122″ and an intermediate metal layer 123″ are sequentially formed on the semiconductor substrate 100. As described above, a bulk substrate or an SOI substrate may be used as the semiconductor substrate 100, and the gate dielectric layer 110 may be formed of a material with a high dielectric constant, i.e., a high-k dielectric material. The intermediate metal layer 123″ may be thinner than the first metal layer 122″.

Referring to FIG. 7B, the intermediate metal layer 123″ is removed in a second device region and a fuse region to expose the first metal layer 122″, and an intermediate metal pattern 123″a is formed only in a first device region. A second metal layer 124″ is formed on the semiconductor substrate 100 including the intermediate metal pattern 123″a.

Referring to FIG. 7C, the first metal layer 122″ and the second metal layer 124″ are removed in the fuse region, and the first and second metal layers 122″ and 124″ are patterned to form a stack pattern of a first portion 122″a of the first metal layer 122″, the intermediate metal pattern 123″a and a first portion 124″a of the second metal layer 124″ in the first device region, and a stack pattern of a second portion 122″b of the first metal layer 122″, and a second portion 124″b of the second metal layer 124″ in the second device region.

Referring to FIG. 7D, a low-resistance layer 126″ is formed on the semiconductor substrate 100 including the stack patterns. The low-resistance layer 126″ may be formed of silicide as described above.

Referring to FIG. 7E, the low-resistance layer 126″ is patterned to form a first low-resistance pattern 126″a, a second low-resistance pattern 126″b, and a fuse pattern 126″c. The first and second gate electrodes 120″a and 120″b are thereby formed. That is, the first gate electrode 120″a including the first portion 122″a of the first metal layer 122″, the intermediate metal pattern 123″a, the first portion 124″a of the second metal layer 124″, and the first low-resistance pattern 126″a is formed in the first device region. And the second gate electrode 120″b including the second portion 122″b of the first metal layer 122″, the second portion 124″b of the second metal layer 124″, and the second low-resistance pattern 126″b is formed in the second device region. In the fuse region, the fuse pattern 126″c is formed, which includes only a portion of the low-resistance layer and does not include the metal layer.

Referring to FIG. 7F, a thermal treatment is performed on the semiconductor substrate 100 including the first and second gate electrodes 120″a and 120″b and the fuse pattern 126″c, thereby converting the first portion 122″a of the first metal layer 122″ and the intermediate metal pattern 123″a of the first gate electrode 120″a of the first device region into an alloy metal pattern 123′″a.

According to the embodiments of the present invention, the gate electrodes including different materials are formed in the first device region and the second device region, or the NMOS region and the PMOS region, respectively. Also, in the fuse region, the fuse pattern and a fuse transistor may be formed only with a low-resistance material such as silicide without using metal. That is, electrical characteristics and integration of a semiconductor device are improved by using a metal dual gate electrode, while electrical fusing is still possible because the fuse pattern does not include a metal layer having high conductivity.

According to embodiments of the present invention, the metal gate electrode is employed to improve electrical performance of the semiconductor device. Also, since a metal layer that is highly conductive is not included in the fuse formed simultaneously with the metal gate electrode, electric fusing is possible.

While embodiments of the present invention have been particularly shown and described with reference to exemplary embodiments thereof, it will be understood by those of ordinary skill in the art that various changes in form and details may be made therein without departing from the spirit and scope of the present invention as defined by the following claims.

What is claimed is:

1. A method of fabricating a semiconductor device comprising a first device region, a second device region and a fuse region, the method comprising:
forming a gate dielectric layer on the semiconductor substrate;
forming a first metal layer on the gate dielectric layer;
forming a portion of the first metal layer in the first device region;
forming a second metal layer on the semiconductor substrate comprising the portion of the first metal layer;
forming a portion of the second metal layer in the second device region;
forming a low-resistance layer on the semiconductor substrate comprising the portion of the first metal layer and the portion of the second metal layer; and
patterning the low-resistance layer to form a first gate electrode comprising the portion of the first metal layer and a first low-resistance pattern in the first device region, a second gate electrode comprising the portion of the second metal layer and a second low-resistance pattern in the second device region, and a fuse pattern of the low-resistance layer in the fuse region.

2. The method of claim 1, wherein the portion of the second metal layer comprises a second portion of the second metal layer, and wherein the method further comprises forming a first portion of the second metal layer on the portion of the first metal layer of the first device region.

3. The method of claim 2, wherein the first gate electrode of the first device region further comprises the first portion of the second metal layer between the portion of the first metal layer and the first low-resistance pattern.

4. The method of claim 1, wherein the gate dielectric layer is formed of a dielectric material having a high dielectric constant of 7 or higher.

5. The method of claim 1, wherein the low-resistance layer is formed of silicide.

6. A method of fabricating a semiconductor device comprising a first device region, a second device region and a fuse region, the method comprising:
forming a gate dielectric layer on a semiconductor substrate;
sequentially forming a first metal layer and an intermediate metal layer on the gate dielectric layer;
forming an intermediate metal pattern from the intermediate metal layer in the first device region;
forming a second metal layer on the semiconductor substrate comprising the intermediate metal pattern;
forming a stack pattern comprising a first portion of the first metal layer, the intermediate metal pattern and a first portion of the second metal layer in the first device region, and a stack pattern comprising a second portion of the first metal layer and a second portion of the second metal layer in the second device region;
forming a low-resistance layer on the semiconductor substrate comprising the stack patterns; and
patterning the low-resistance layer to form a first gate electrode in the first device region, a second gate electrode in the second device region and a fuse pattern of the low-resistance layer in the fuse region.

7. The method of claim 6, further comprising forming an alloy metal pattern of the first portion of the first metal layer and the intermediate metal pattern in the first device region by performing a thermal treatment after the forming of the stack patterns.

8. The method of claim 6, wherein the gate dielectric layer is formed of a dielectric material having a high dielectric constant of 7 or higher.

9. The method of claim 6, wherein the low-resistance layer is formed of silicide.
